(19) United States
(12) Patent Application Publication
(10) Pub. No.: US 2012/0321790 A1
(43) Pub. Date: Dec. 20, 2012

(54) ROTATION SYSTEM FOR THIN FILM FORMATION

(75) Inventors: Cheng Chia Fang, Taipei City (TW); Cheng Chieh Yang, Taoyuan City (TW)

(73) Assignee: PINECONE MATERIAL INC., Taipei (TW)

(21) Appl. No.: 13/354,225

(22) Filed: Jan. 19, 2012

Related U.S. Application Data
(63) Continuation-in-part of application No. 13/162,431, filed on Jun. 16, 2011.

(51) Int. Cl. C23C 16/458; C23C 16/455

(52) U.S. Cl. 427/255.28; 118/500; 118/730; 427/255.5

(57) ABSTRACT

A system for forming one or more layers of material on one or more substrates is disclosed. The system includes a susceptor that rotates around a central susceptor axis. One or more holder gears are located on the susceptor. The holder gears may rotate around the central susceptor axis with the susceptor. A central gear engaged to the holder gears may cause the holder gears to rotate around holder axes of the respective holder gears while the holder gears rotate around the central susceptor axis. The susceptor and the central gear may rotate independently.

### PRIORITY CLAIM

This patent application is a continuation-in-part of U.S. patent application Ser. No. 13/162,431 entitled “ROTATION SYSTEM FOR THIN FILM FORMATION AND METHOD THEREOF” to Fang et al. filed on Jun. 16, 2011.

### RELATED PATENT

This patent application is related to copending U.S. patent application Ser. No. 13/282,161 entitled “ROTATION SYSTEM FOR THIN FILM FORMATION” to Yang et al. filed on Oct. 26, 2011 which is incorporated by reference as if fully set forth herein.

### BACKGROUND

1. Field of the Invention

The present invention relates to a thin film deposition apparatus. More particularly the invention relates to a rotation system for deposition of thin film materials on substrates.

2. Description of Related Art

Thin film deposition has been widely used for surface processing of various objects such as jewelry, dishware, tools, molds, and/or semiconductor devices. Often, thin films of homogeneous or heterogeneous compositions are formed on surfaces of metals, alloys, ceramics, and/or semiconductors to improve, for example, wear resistance, heat resistance, and/or corrosion resistance. The techniques of thin film deposition are typically classified into at least two categories—physical vapor deposition (PVD) and chemical vapor deposition (CVD).

Depending on the deposition technique and process parameters, the deposited thin films may have a crystalline, polycrystalline, or amorphous structure. Crystalline and/or polycrystalline thin films often are formed as epitaxial layers, which are important in the fabrication of semiconductor devices and integrated circuits. For example, epitaxial layers may be made of semiconductor layers and doped during formation to produce dopant profiles under conditions (e.g., vacuum conditions) that inhibit contamination by oxygen and/or carbon impurities.

One type of CVD process is called metal-organic chemical vapor deposition (MOCVD). For MOCVD, one or more carrier gases are used to carry one or more gas-phase reagents and/or precursors into a reaction chamber (e.g., a vacuum chamber) that contains one or more substrates (e.g., semiconductor substrates (wafers)). The backsides of the substrates are usually heated through radio-frequency (RF) induction or by a resistive heating element to raise the temperature of the substrates. At the elevated temperature, one or more chemical reactions may occur that convert the reagents and/or precursors (e.g., in gas phase) into one or more solid products that are deposited on the surfaces of the substrates.

In certain processes, epitaxial layers made by MOCVD are used to make light emitting diodes (LEDs). The quality of LEDs formed using MOCVD are affected by various factors such as, but not limited to, flow stability or uniformity inside the reaction chamber, flow uniformity across the substrate surfaces, and/or accuracy of temperature control. Variations in these factors may adversely affect the quality of epitaxial layers formed using MOCVD and, hence, the quality of LEDs produced using MOCVD.

Thus, there is a need for systems and methods that improve techniques for forming epitaxial layers using MOCVD. Particularly, there is a need for improvement of flow uniformity in the vacuum chamber and across the surfaces of the substrates during deposition of the epitaxial layers.

### SUMMARY

In certain embodiments, a system for forming one or more layers of material on one or more substrates includes a susceptor that rotates around a central susceptor axis. One or more holder gears located on the susceptor may rotate around the central susceptor axis with the susceptor. A central gear engaged to the holder gears may cause the holder gears to rotate around holder axes of the respective holder gears while the holder gears rotate around the central susceptor axis. The susceptor and the central gear may rotate independently.

In certain embodiments, a method for forming one or more layers of material on one or more substrates includes rotating the one or more substrates around a central susceptor axis on one or more holder gears located on a susceptor. The holder gears may rotate around holder axes of the respective holder gears with a central gear while the holder gears rotate around the central susceptor axis. The central gear may rotate independently of the susceptor. The one or more layers of material may be formed on the one or more substrates while the substrates rotate around the central susceptor axis and the holder axes.

In some embodiments, the susceptor is coupled to a rotatable member that rotates around a shaft. In some embodiments, the rotatable member includes a bushing that encloses the shaft coupled to the central gear and the bushing rotates freely around the shaft. In some embodiments, the rotatable member includes a rotating shell coupled to the susceptor. In some embodiments, the central gear remains fixed during use. In some embodiments, the central gear rotates in a same direction as the susceptor. In some embodiments, the central gear rotates at the same speed as the susceptor. In some embodiments, the central gear rotates at a different speed from the susceptor. In some embodiments, the central gear rotates in an opposite direction from the susceptor.

### BRIEF DESCRIPTION OF THE DRAWINGS

Features and advantages of the methods and apparatus of the present invention will be more fully appreciated by reference to the following detailed description of presently preferred but nonetheless illustrative embodiments in accordance with the present invention when taken in conjunction with the accompanying drawings in which:

FIGS. 1A and 1B depict representations of an embodiment of a rotation system for forming one or more materials on one or more substrates.

FIG. 2A depicts a representation of an embodiment of a rotation system with a central gear engaged to holder gears.

FIG. 2B depicts a representation of an embodiment of a rotation system with a substrate holder, a holder gear, and a holder ring in an assembled condition.

FIG. 3 depicts a representation of an embodiment showing rotation of a substrate holder as part of the rotation system for forming one or more materials on one or more substrates.

FIG. 4 depicts a representation of another embodiment showing rotation of a substrate holder as part of the rotation system for forming one or more materials on one or more substrates.

FIGS. 5A and 5B depict representations of an embodiment of a reaction system that includes a rotation system for forming one or more materials on one or more substrates.

FIG. 6 depicts a top view representation of an embodiment of a rotation system having a susceptor with holder gears separated from each other around a central gear.

FIG. 7 depicts a top view representation of an embodiment of a rotation system having a susceptor with holder gears at least partially overlapping each other around a central gear.

FIG. 8 depicts a side view representation of an embodiment of at least partially overlapping areas between teeth of holder gears.

FIG. 9 depicts an embodiment of a rotation system with a rotatable member and a shaft.

FIG. 10 depicts an embodiment of a rotation system showing the interaction of holder gears and a central gear.

FIG. 11 depicts a top view of an embodiment of a rotation system with a susceptor rotating clockwise and a central gear rotating counterclockwise.

While the invention is susceptible to various modifications and alternative forms, specific embodiments thereof are shown by way of example in the drawings and will herein be described in detail. The drawings may not be to scale. It should be understood that the drawings and detailed description thereto are not intended to limit the invention to the particular form disclosed, but to the contrary, the intention is to cover all modifications, equivalents and alternatives falling within the spirit and scope of the present invention as defined by the appended claims.

### DETAILED DESCRIPTION OF EMBODIMENTS

In the context of this patent, the term “coupled” means either a direct connection or an indirect connection (e.g., one or more intervening connections) between one or more objects or components.

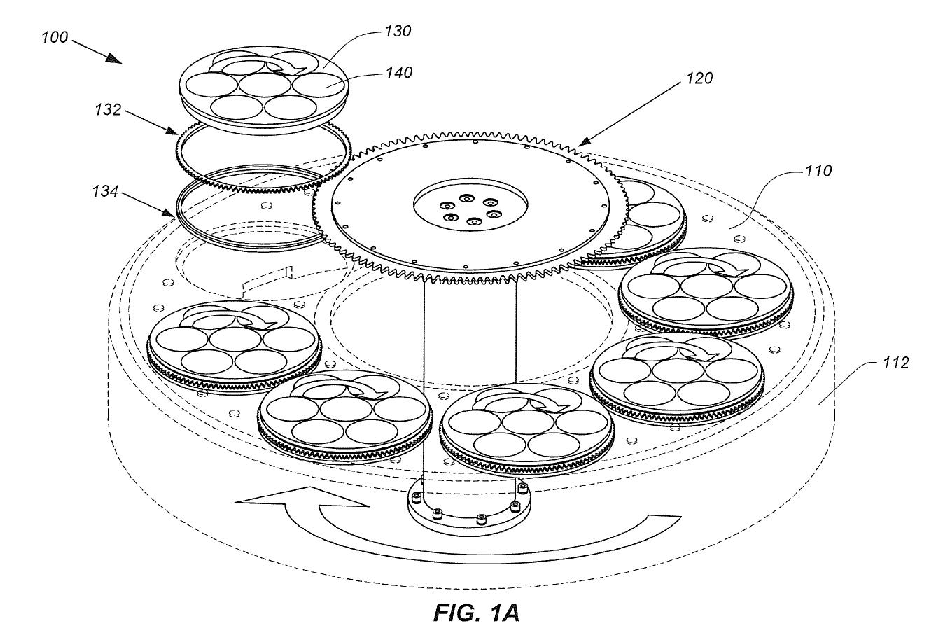

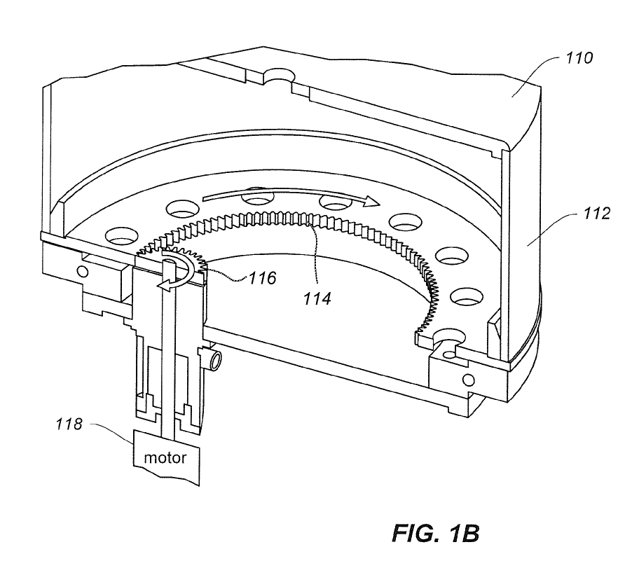

FIGS. 1A and 1B depict representations of an embodiment of rotation system 100 for forming one or more materials on one or more substrates. In certain embodiments, rotation system 100 includes susceptor 110, rotating shell 112, internal gear 114, external gear 116, and motor 118. In some embodiments, rotation system 100 includes central gear 120. In certain embodiments, rotation system 100 includes one or more substrate holders 130, one or more holder gears 132, and one or more holder rings 134. In certain embodiments, substrate holder 130 is used to hold substrates 140 (e.g., one or more wafers). In some embodiments, internal gear 114 and external gear 116 form a driving assembly, which may include motor 118.

Although the above has been shown using a selected group of components for the system 100, there can be many alternatives, modifications, and variations. For example, some of the components may be expanded and/or combined. Other components may be inserted to those noted above. Depending upon the embodiment, the arrangement of components may be interchanged with others replaced.

In certain embodiments, rotating shell 112 is fixed to internal gear 114 at the bottom and supports, directly or indirectly, susceptor 110 at the top. In some embodiments, rotating shell 112 is fixed to susceptor 110 at the top. In another embodiment, internal gear 114 is engaged to external gear 116. In yet another embodiment, external gear 116 is driven to rotate by motor 118, causing the internal gear to also rotate. The rotation of internal gear 114 brings rotating shell 112 and susceptor 110 to rotate around a common axis (e.g., a susceptor axis) according to one embodiment. For example, rotating shell 112 can rotate using a slewing bearing.

In certain embodiments, on susceptor 110, there are one or more substrate holders 130, one or more holder gears 132, and one or more holder rings 134. In some embodiments, substrate holders 130, holder gears 132, and holder rings 134 rotate around the common axis with susceptor 110. In some embodiments, each of holder gears 132 supports substrate holder 130 and each of substrate holders 130 carries one or more substrates 140 (e.g., one or more wafers).

In some embodiments, central gear 120 is engaged to one or more of holder gears 132. In one embodiment, central gear 120 is stationary when holder gears 132 rotate around the common axis with susceptor 110, causing holder gears 132 to rotate around their corresponding holder axes respectively.

In another embodiment, central gear 120 rotates around the common axis in one direction at an angular speed when holder gears 132 rotate around the common axis with susceptor 110 in the same direction but at a different speed. The rotation of central gear 120 causes holder gears 132 to rotate around their corresponding holder axes respectively. In certain embodiments, the angular speed of rotation by holder gears 132 around their corresponding holder axes is determined by the gear ratio between central gear 120 and each of the holder gears and by the angular-speed ratio between the central gear and each of the holder gears around the common axis.

In yet another embodiment, central gear 120 rotates around the common axis in one direction, when holder gears 132 rotate around the common axis with the susceptor 110 in another direction, causing the one or more holder gears 132 to rotate around their corresponding holder axes respectively.

In certain embodiments, holder gears 132 are fixed with substrate holders 130 such that the substrate holders also rotate around their corresponding holder axes, respectively. In some embodiments, holder gears 132 are in contact with holder rings 134 through one or more ball bearings, respectively. In some embodiments, holder rings 134 are fixed with susceptor 110 so they do not rotate around the holder axes with holder gears 132.

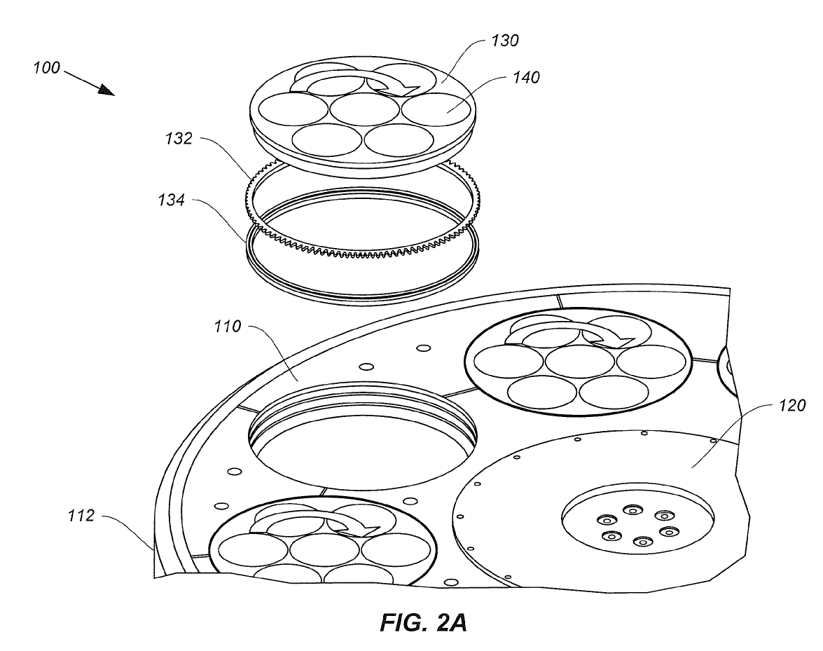

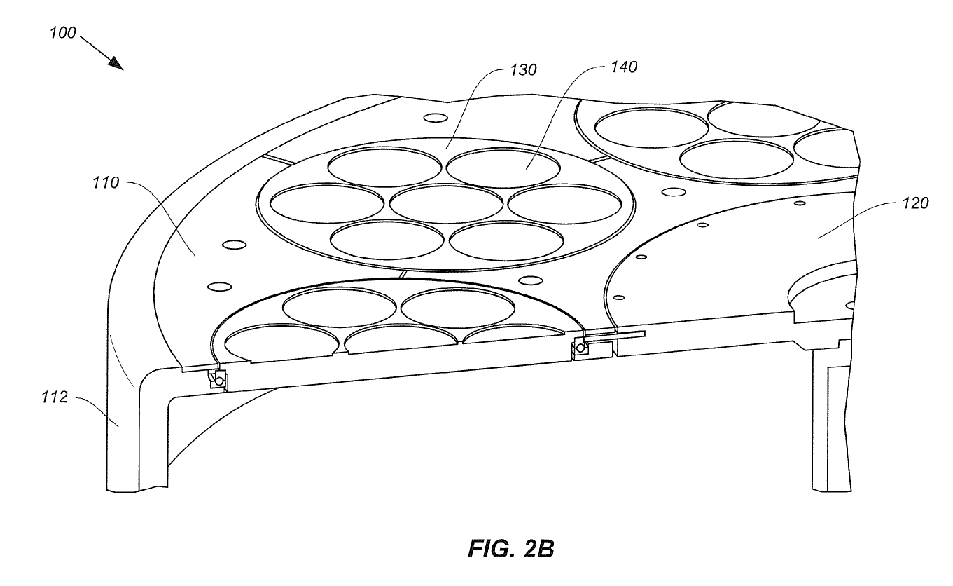

As shown in FIG. 1A, substrate holder 130, holder gear 132, and holder ring 134 are shown in a disassembled condition and central gear 120 is shown detached from the holder gears in order to clearly depict these components. FIG. 2A depicts a representation of an embodiment of rotation system 100 with central gear 120 engaged to holder gears 132. Additionally, FIG. 2B depicts a representation of an embodiment of rotation system 100 with substrate holder 130, holder gear 132, and holder ring 134 in an assembled condition.

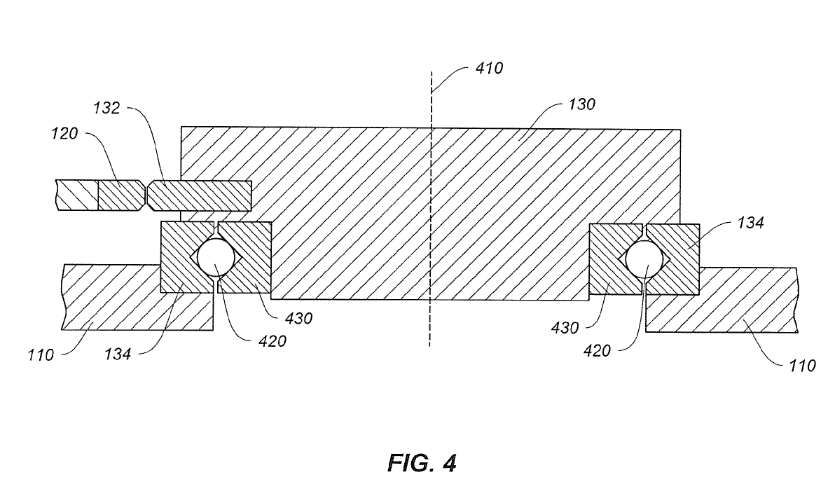

As discussed above and further emphasized here, FIGS. 1A, 1B, 2A, and 2B are merely examples, which should not unduly limit the scope of the claims. One of ordinary skill in the art would recognize many variations, alternatives, and modifications. For example, one or more substrate holders 130 may be removed so that one or more of holder gears 132 can directly support one or more substrates 140 (e.g., one or more wafers). Substrates 140 may rotate with corresponding holder gear 132 around the common axis and/or around the corresponding holder axis. In another example, one or more holder rings 134 may be removed as shown in FIG. 4.

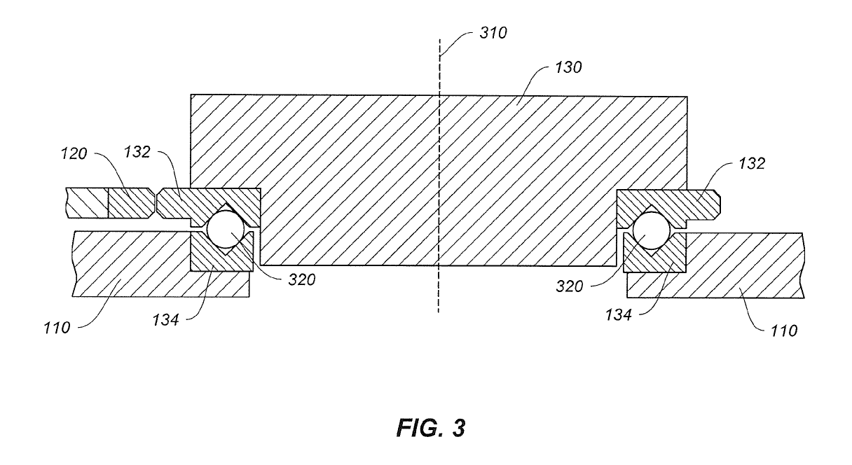

FIG. 3 depicts a representation of an embodiment showing rotation of substrate holder 130 as part of rotation system 100 for forming one or more materials on one or more substrates. As shown in FIG. 3, each of holder gears 132 forms a hollow ring that is used to support its corresponding substrate holder 130. In certain embodiments, each of holder gears 132 and its corresponding substrate holder 130 rotates around holder axis 310 using ball bearing 320. In another embodiment, ball bearing 320 is located between a bottom groove of holder gear 132 and a top groove of holder ring 134. In yet another embodiment, holder ring 134 is fixed to susceptor 110.

FIG. 4 depicts a representation of another embodiment showing rotation of substrate holder 130 as part of rotation system 100 for forming one or more materials on one or more substrates. As shown in FIG. 4, each of holder gears 132 forms a hollow ring that is used to support its corresponding substrate holder 130. In certain embodiments, each of holder gears 132 and its corresponding substrate holder 130 rotates around holder axis 410 using ball bearing 420. In another embodiment, ball bearing 420 is located between grooves of inner ring 430 and holder ring 134. In some embodiments, inner ring 430 is fixed to substrate holder 130.

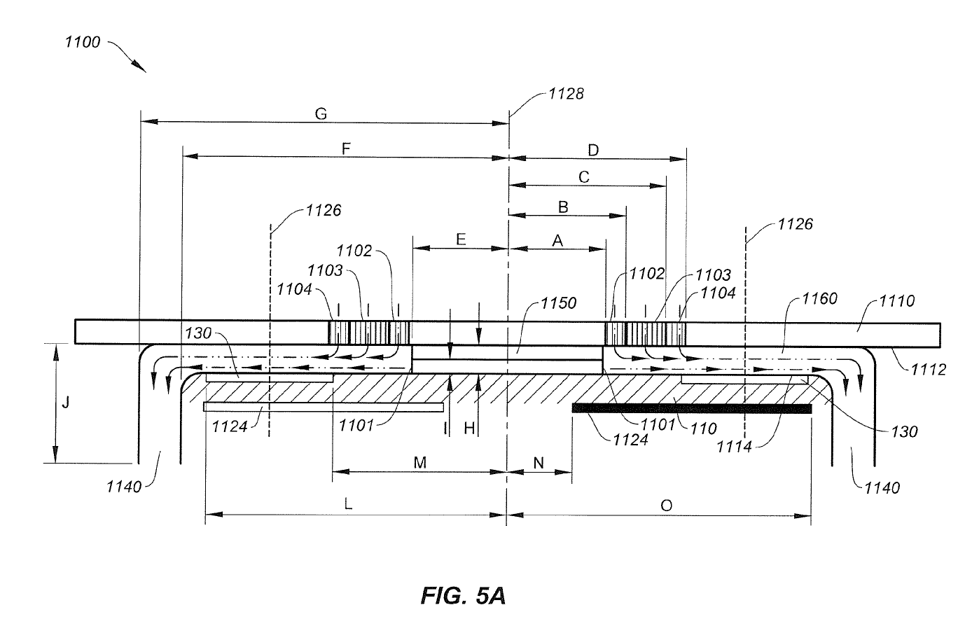

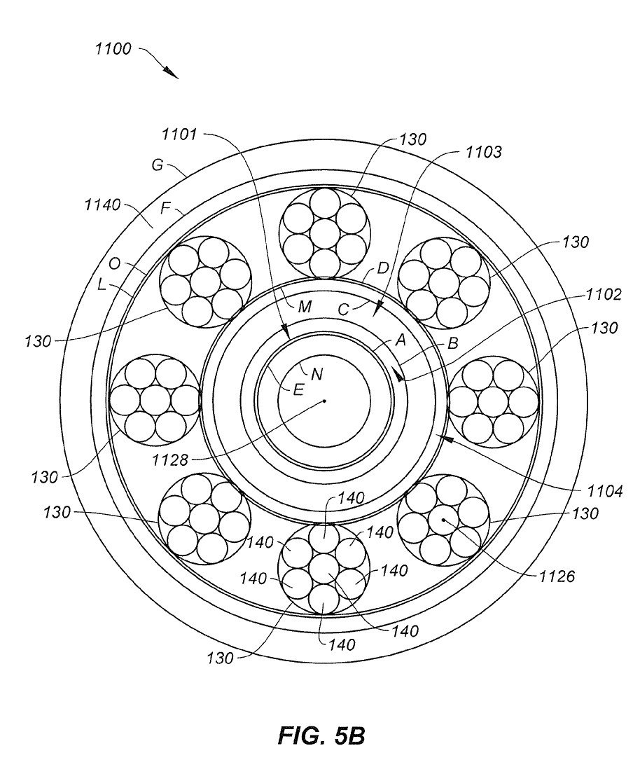

FIGS. 5A and 5B depict representations of an embodiment of a reaction system that includes rotation system 100 for forming one or more materials on one or more substrates. FIG. 5A shows a side view of reaction system 1100 and FIG. 5B shows a planar view of the reaction system. Reaction system 1100 may be, for example, a vacuum system for depositing thin films onto one or more substrates. In one embodiment, reaction system 1100 is a chemical vapor deposition (CVD) system (e.g., a metal organic CVD (MOCVD) system).

In certain embodiments, reaction system 1100 includes showerhead component 1110, susceptor 110, inlets 1101, 1102, 1103 and 1104, one or more substrate holders 130, one or more heating devices 1124, an outlet 1140, and a central component 1150. In some embodiments, central component 1150, showerhead component 1110, susceptor 110, and one or more substrate holders 130 (e.g., located on the susceptor) form reaction chamber 1160 with inlets 1101, 1102, 1103 and 1104 and outlet 1140. In some embodiments, one or more substrate holders 130 are each used to carry one or more substrates 140 (e.g., one or more wafers).

Although the above has been shown using a selected group of components for system 1100, there can be many alternatives, modifications, and variations. For example, some of the components may be expanded and/or combined. Other components may be inserted to those noted above. Depending upon the embodiment, the arrangement of components may be interchanged with others replaced.

In certain embodiments, inlet 1101 is formed within central component 1150 and provides one or more gases in a direction that is substantially parallel to surface 1112 of showerhead component 1110. In some embodiments, central component 1150 is located above (e.g., on) central gear 120. In some embodiments, one or more gases flows (e.g., flows up) into reaction chamber 1160 near the center of the reaction chamber and then flows through inlet 1101 outward radially, away from the center of the reaction chamber. In certain embodiments, inlets 1102, 1103 and 1104 are formed within showerhead component 1110 and provide one or more gases in a direction that is substantially perpendicular to surface 1112.

In certain embodiments, various kinds of gases may be provided through inlets 1101, 1102, 1103 and 1104. Examples of gases are shown in Table 1.

TABLE 1

| Inlets | 1101 | 1102 | 1103 | 1104 |
|---|---|---|---|---|
| Gases | NH₃ | N₂, H₂, and/or | N₂, I-h, and/or | N₂, H₂, and/or |
| | | TMG | NH₃ | TMG |

In certain embodiments, susceptor 110 rotates around susceptor axis 1128 (e.g., a central axis), and each of substrate holders 130 rotates around corresponding holder axis 1126 (e.g., holder axis 310 or 410). In some embodiments, substrate holders 130 can rotate, with susceptor 110, around susceptor axis 1128, and also rotate around their corresponding holder axes 1126. For example, substrates 140 on same substrate holder 130 can rotate around same holder axis 1126.

In certain embodiments, inlets 1101, 1102, 1103 and 1104, and outlet 1140 each have a circular configuration around susceptor axis 1128. In some embodiments, substrate holders 130 (e.g., eight substrate holders 130) are arranged around susceptor axis 1128. For example, each of substrate holders 130 can carry several substrates 140 (e.g., seven substrates 140).

As shown in FIGS. 5A and 5B, symbols A, B, C, D, E, F, G, H, I, J, L, M, N, and 0 represent various dimensions of reaction system 1100 according to some embodiments. In one embodiment,
(1) A represents the distance between susceptor axis 1128 and the inner edge of inlet 1102;
(2) B represents the distance between susceptor axis 1128 and the inner edge of inlet 1103;
(3) C represents the distance between susceptor axis 1128 and the inner edge of inlet 1104;
(4) D represents the distance between susceptor axis 1128 and the outer edge of inlet 1104;
(5) E represents the distance between susceptor axis 1128 and inlet 1101;
(6) F represents the distance between susceptor axis 1128 and the inner edge of outlet 1140;
(7) G represents the distance between susceptor axis 1128 and the outer edge of outlet 1140;
(8) H represents the distance between surface 1112 of showerhead component 1110 and surface 1114 of susceptor 110;
(9) I represents the height of inlet 1101;
(10) J represents the distance between surface 1112 of showerhead component 1110 and outlet 1140;
(11) L represents the distance between susceptor axis 1128 and one or more outer edges of one or more substrate holders 130 respectively;
(12) M represents the distance between susceptor axis 1128 and one or more inner edges of one or more substrate holders 130 respectively;
(13) N represents the distance between susceptor axis 1128 and one or more inner edges of one or more heating devices 1124 respectively; and
(14) O represents the distance between susceptor axis 1128 and one or more outer edges of one or more heating devices 1124 respectively.

In certain embodiments, L minus M is the diameter of substrate holders 130. In some embodiments, the vertical size of reaction chamber 1160 (e.g., represented by H) is equal to or less than 20 mm, or is equal to or less than 15 mm. In some embodiments, the vertical size of inlet 1101 (e.g., represented by I) is less than the vertical distance between surface 1112 of showerhead component 1110 and surface 1114 of susceptor 110 (e.g., represented by H). In some embodiments, some magnitudes of these dimensions are shown in Table 2 below.

TABLE 2

| Dimension Symbol | Dimension Magnitude (mm) |
|---|---|
| A | 105 |
| B | 120 |
| C | 150 |
| D | 165 |
| E | 100 |
| F | 330 |
| G | 415 |
| H | 10 |
| I | 5 |
| J | 150 |
| L | 310 |
| M | 145 |
| N | 96 |
| O | 320 |

In certain embodiments, substrate holders 130 are located on susceptor 110. In some embodiments, heating devices 1124 are located under substrate holders 130 respectively. In some embodiments, heating devices 1124 extend toward the center of reaction chamber 1160 beyond substrate holders 130 respectively. In certain embodiments, heating devices 1124 preheat the one or more gases from inlets 1101, 1102, 1103, and/or 1104 before the gases reach substrate holders 130.

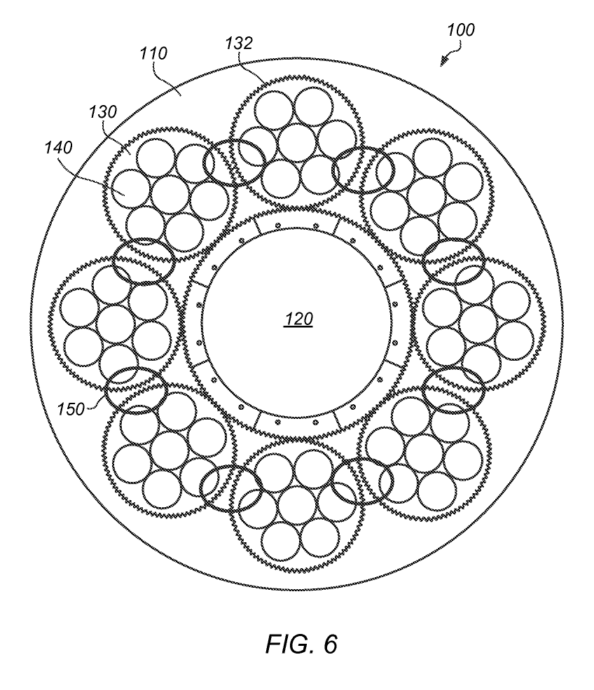

In certain embodiments, holder gears 132 are separated from each other around central gear 120. FIG. 6 depicts a top view representation of an embodiment of rotation system 100 having susceptor 110 with holder gears 132 separated from each other around central gear 120. Holder gears 132 support substrate holders 130 and substrates 140. In certain embodiments, holder gears 132 and substrate holders 130 are formed as a single piece. In some embodiments, holder gears 132 and substrate holders 130 are separate pieces.

Central gear 120 engages holder gears 132 using, for example, teeth on the respective gears. As shown in FIG. 6, holder gears 132 are separated around central gear 120, shown by spaces 150. Holder gears 132 are separated to inhibit interaction between teeth of adjacent holder gears and ensure smoother rotation of the holder gears. Separating holder gears 132 by spaces 150, however, may increase the area of susceptor 110. Additionally, high heat outputs from a heater may be required to raise the temperatures of each individual holder gear 132 and/or each substrate holder 130 to desired temperatures because of the separation between the holder gears.

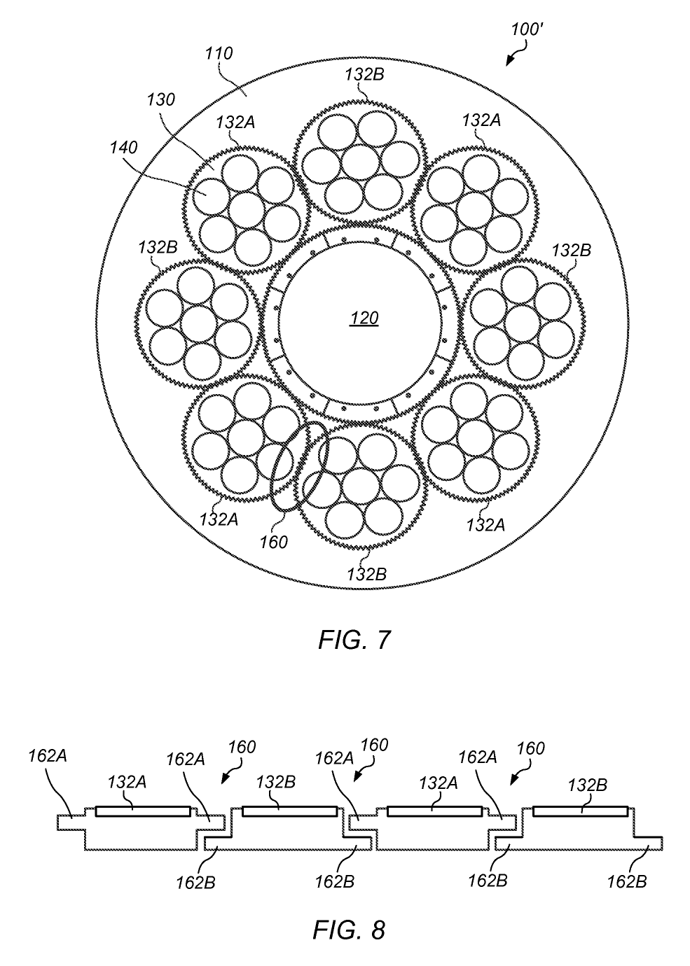

To overcome some of the problems associated with holder gears 132 being separated, the holder gears may be designed to at least partially overlap and reduce the separation between the holder gears. FIG. 7 depicts a top view representation of an embodiment of rotation system 100′ having susceptor 110 with holder gears 132 at least partially overlapping each other around central gear 120. In certain embodiments, holder gears 132A have gear teeth that overlap with gear teeth of holder gears 132B with holder gears 132A alternating with holder gears 132B around central gear 120.

FIG. 8 depicts a side view representation of an embodiment of the at least partially overlapping areas (as represented by oval 160 in FIG. 7) between teeth of holder gears 132A and teeth of holder gears 132B. Holder gears 132A have teeth 162A on each side of the holder gears. Holder gears 132B have teeth 162B on each side of the holder gears. Teeth 162A and 162B are designed to engage central gear 120 (shown in FIG. 7) such that holder gears 132A and 132B are rotated around their holder axes as the holder gears rotate around the central susceptor axis.

As shown in FIG. 8, teeth 162A at least partially overlap teeth 162B without the teeth touching each other. For example, holder gears 132A have teeth 162A that are above teeth 162B of holder gears 132B and the teeth do not touch each other. Having teeth 162A at least partially overlap teeth 162B allows holder gears 132A to at least partially overlap holder gears 132B (as shown in FIG. 7) while allowing for smooth rotation of the holder gears because the holder gears do not interact with (engage) each other (e.g., the teeth only engage central gear 120 and do not interfere with each other).

At least partially overlapping holder gears 132A and 132B allows the occupied area of susceptor 110 to be reduced because there is no space between the holder gears (as shown in FIG. 6). Reducing the occupied area on susceptor 110 may allow the area of the susceptor to be reduced. Reducing susceptor 110 size may allow size of the reaction system (e.g., reaction system 1100 depicted in FIG. 5A) or vacuum chamber to be reduced.

In certain embodiments, the size of central gear 120 is reduced with overlapping holder gears 132A and 132B. Because of the overlapping holder gears, the holder gears form a smaller diameter circle and the diameter of central gear 120 may be reduced to fit the smaller diameter circle. In certain embodiments, the thickness of teeth on central gear 120 is more than the thickness of teeth 162A and 162B of the individual holder gears 132A and 132B. For example, central gear 120 may have teeth with a height (thickness) that is large enough to engage both teeth 162A (upper teeth) and teeth 162B (lower teeth), as shown in FIG. 8. Thus, central gear 120 may engage both teeth 162A and 162B simultaneously and without the need for multiple levels of teeth.

In addition, because holder gears 132A at least partially overlap with holder gears 132B, as shown in FIG. 7, (and, in some embodiments, because susceptor 110 and central gear 120 have smaller dimensions), less overall heat output is needed to raise the temperatures of the holder gears and the substrate holders 130 to desired temperatures. Heat output may be reduced because the overall total area to be heated (e.g., the area of susceptor 110) is reduced with the overlap between the holder gears.

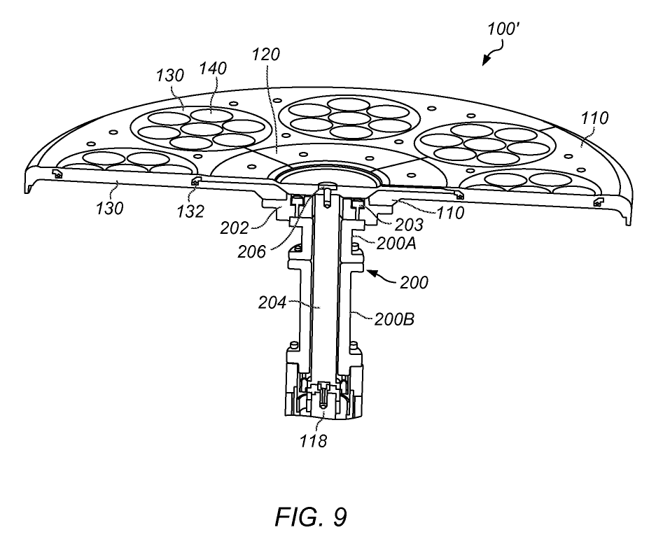

FIG. 9 depicts an embodiment of a rotation system with a rotatable member and a shaft. In certain embodiments, rotation system 100′ includes susceptor 110 and central gear 120. In certain embodiments, rotation system 100′ includes one or more substrate holders 130, one or more holder gears 132, and one or more holder rings 134. In certain embodiments, substrate holder 130 is used to hold substrates 140 (e.g., one or more wafers).

In certain embodiments, susceptor 110 is coupled (joined) to rotatable member 200 using adaptor 202. In some embodiments, adaptor 202 is coupled to rotatable member 200 using fastener 203. Fastener 203 may be, for example, a bolt. Rotatable member 200 may be coupled to and driven by motor 118. Rotatable member 200 is coupled to susceptor 110 with adaptor 202 such that rotation of the rotatable member rotates the susceptor around the central susceptor axis (e.g., the central axis of the bushing). In certain embodiments, adaptor 202 is made of quartz or another suitable thermally insulating material. Adaptor 202 may inhibit susceptor 110 from cracking or damage when the susceptor is heated to high temperatures (e.g., temperatures of about 1400° C.).

In certain embodiments, rotatable member 200 includes two sections 200A, 200B. Separating rotatable member 200 into multiple sections allows the rotatable member sections to maintain parallel alignment between susceptor 110 and the showerhead. In certain embodiments, rotatable member 200 includes a bushing. In some embodiments, rotatable member 200 includes two or more bushings. For example, sections 200A, 200B of rotatable member 200 may each include a bushing. The bushings in each section may interact to maintain parallel alignment between susceptor 110 and the showerhead. In some embodiments, rotatable member 200 includes a rotating shell coupled to susceptor 110.

In certain embodiments, shaft 204 is enclosed inside rotatable member 200 (e.g., the shaft is enclosed inside the bushing(s) of the rotatable member). Rotatable member 200 encloses shaft 204 in such a manner that allows the rotatable member (e.g., bushing) to rotate freely around the shaft. Shaft 204 is coupled to central gear 120. In some embodiments, shaft 204 is coupled to central gear 120 using fastener 206. Fastener 206 may be, for example, a bolt. In certain embodiments, shaft 204 is a fixed shaft (e.g., the shaft does not rotate). In some embodiments, shaft 204 rotates. Shaft 204 and central gear 120 are coupled such that rotation of the shaft rotates the central gear around the central susceptor axis (e.g., the central axis of the shaft). Shaft 204 may rotate independently from rotatable member 200 (e.g., rotate independently of the bushing). Thus, central gear 120 and susceptor 110 may rotate independently.

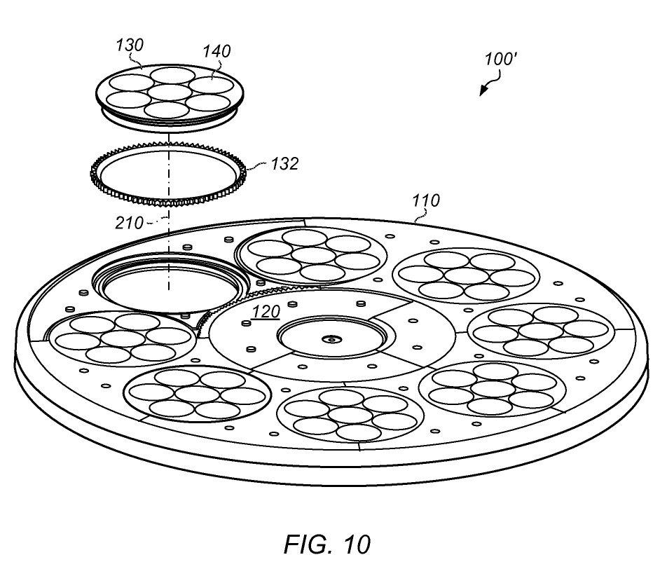

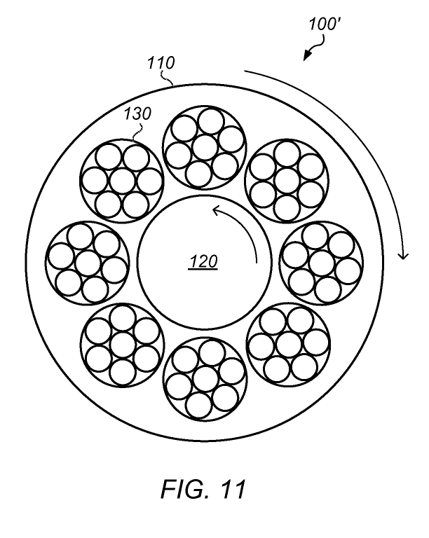

Because central gear 120 and susceptor 110 may rotate independently, there are several possible embodiments for relative rotation of the central gear and the susceptor. Additionally, because the rotation of substrate holders 130 is controlled by the rotation of central gear 120 through the interaction of the central gear and holder gears 132 (shown in FIG. 10), the relative rotation of the central gear and susceptor 120 controls the relationship between the rotation speed of the substrate holders around holder axis 210 and the rotation speed of the susceptor around the axis of the rotatable member (e.g., the susceptor axis). FIG. 11 depicts a top view of an embodiment of rotation system 100′ with susceptor 110 rotating clockwise and central gear 120 rotating counterclockwise.

In one embodiment, susceptor 110 is rotated clockwise (or counterclockwise) while central gear 120 is not rotated (fixed) with respect to the susceptor axis. In such an embodiment, substrate holders 130 rotate around their respective holder axes at a speed controlled by the rotation speed of the susceptor. Such a rotation speed for the substrate holders may be referred to as a standard (normal) rotation speed.

In another embodiment, susceptor 110 is rotated clockwise (or counterclockwise) while central gear 120 also rotates in the same, clockwise (or counterclockwise) direction at a slower rotational speed. In such an embodiment, substrate holders 130 rotate around their respective holder axes at a rotation speed that is slower than the standard rotation speed.

In yet another embodiment, susceptor 110 is rotated clockwise (or counterclockwise) while central gear 120 rotates in the opposite, counterclockwise (or clockwise) direction (e.g., as shown in FIG. 11). In such an embodiment, substrate holders 130 rotate around their respective holder axes at a rotation speed that is faster than the standard rotation speed.

In some embodiments, susceptor 110 is rotated clockwise (or counterclockwise) while central gear 120 also rotates in the same, clockwise (or counterclockwise) direction at an identical rotational (angular) speed. In such an embodiment, substrate holders 130 appear fixed to their respective holder axes.

It is to be understood the invention is not limited to particular systems described which may, of course, vary. For example, as shown in FIGS. 5A and 5B, inlet 1102 may be replaced by a plurality of inlets and/or inlet 1104 may be replaced by another plurality of inlets. As another example, inlet 1102 may be formed within central component 1150 and configured to provide one or more gases in a direction that is substantially parallel to surface 1112 of showerhead component 1110. It is also to be understood that the terminology used herein is for the purpose of describing particular embodiments only, and is not intended to be limiting. As used in this specification, the singular forms “a”, “an” and “the” include plural referents unless the content clearly indicates otherwise. Thus, for example, reference to “a device” includes a combination of two or more devices and reference to “a material” includes mixtures of materials.

The present invention is directed to methods and systems of material fabrication. More particularly, the invention provides a rotation system and related method for forming epitaxial layers of semiconductor materials. Merely by way of example, the invention has been applied to metal-organic chemical vapor deposition, but it would be recognized that the invention has a much broader range of applicability.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A system for forming one or more layers of material on one or more substrates, comprising:
a susceptor configured to rotate around a central susceptor axis;
one or more holder gears located on the susceptor, wherein the holder gears are configured to rotate around the central susceptor axis with the susceptor; and
a central gear engaged to the holder gears, wherein the central gear is configured to cause the holder gears to rotate around holder axes of the respective holder gears while the holder gears rotate around the central susceptor axis;
wherein the susceptor and the central gear are configured to rotate independently.

2. The system of claim 1, wherein the susceptor is coupled to a rotatable member that rotates around a shaft coupled to the central gear.

3. The system of claim 2, wherein the rotatable member comprises a bushing that encloses the shaft coupled to the central gear, and wherein the bushing rotates freely around the shaft.

4. The system of claim 3, wherein the susceptor is coupled to the bushing using an adaptor.

5. The system of claim 4, wherein the adaptor comprises quartz.

6. The system of claim 3, wherein the bushing comprises at least two sections.

7. The system of claim 2, wherein the rotatable member comprises a rotating shell coupled to the susceptor.

8. The system of claim 1, wherein the central susceptor axis is different from the holder axes.

9. The system of claim 1, wherein the central gear is centered on the central susceptor axis.

10. The system of claim 1, wherein the central gear is configured to remain fixed during use.

11. The system of claim 1, wherein the central gear is configured to rotate in a same direction as the susceptor.

12. The system of claim 1, wherein the central gear is configured to rotate in a same direction as the susceptor and at a same angular speed as the susceptor.

13. The system of claim 1, wherein the central gear is configured to rotate in an opposite direction from the susceptor.

14. The system of claim 1, wherein the one or more holder gears are configured to support one or more substrates.

15. The system of claim 1, wherein the one or more holder gears comprise substrate holders.

16. The system of claim 1, further comprising one or more substrate holders coupled to the one or more holder gears.

17. The system of claim 1, further comprising a showerhead located above the susceptor.

18. The system of claim 1, further comprising one or more heating devices located below the holder gears.

19. A method for forming one or more layers of material on one or more substrates, comprising:
rotating the one or more substrates around a central susceptor axis on one or more holder gears located on a susceptor;
causing the holder gears to rotate around holder axes of the respective holder gears with a central gear while the holder gears rotate around the central susceptor axis, wherein the central gear rotates independently of the susceptor; and
forming the one or more layers of material on the one or more substrates while the substrates rotate around the central susceptor axis and the holder axes.

20. The method of claim 19, further comprising forming the one or more layers of material on the one or more substrates by chemical vapor deposition.

21. The method of claim 19, wherein the one or more holder gears comprise substrate holders.

22. The method of claim 19, further comprising locating the one or more substrates on one or more substrate holders coupled to the one or more holder gears.

23. The method of claim 19, wherein the susceptor is coupled to a rotatable member that rotates around a shaft coupled to the central gear.

24. The method of claim 23, wherein the rotatable member comprises a bushing that encloses the shaft coupled to the central gear, and wherein the bushing rotates freely around the shaft.

25. The method of claim 23, wherein the rotatable member comprises a rotating shell coupled to the susceptor.

26. The method of claim 19, wherein the central gear does not rotate while the susceptor rotates around the central susceptor axis.

27. The method of claim 19, wherein the central gear rotates in a same direction as the susceptor.

28. The method of claim 27, wherein the central gear rotates at the same speed as the susceptor.

29. The method of claim 27, wherein the central gear rotates at a different speed from the susceptor.

30. The method of claim 19, wherein the central gear rotates in an opposite direction from the susceptor.
